(19) United States
(12) Patent Application Publication
(10) Pub. No.: US 2024/0052492 A1
(43) Pub. Date: Feb. 15, 2024

(54) LITHIUM LANTHANUM ZIRCONATE THIN FILMS

(71) Applicants: Candace Chan, Phoenix, AZ (US); Jon Mark Weller, Phoenix, AZ (US)

(72) Inventors: Candace Chan, Phoenix, AZ (US); Jon Mark Weller, Phoenix, AZ (US)

(21) Appl. No.: 18/493,561

(22) Filed: Oct. 24, 2023

Related U.S. Application Data
(63) Continuation of application No. 17/685,923, filed on Mar. 3, 2022, now Pat. No. 11,807,944.
Application No. 17/685,923 is a division of application No. 16/669,767, filed on Oct. 31, 2019, now Pat. No. 11,268,196.
(60) Provisional application No. 62/753,503, filed on Oct. 31, 2018.

(51) Int. Cl. C23C 22/70; C23C 16/40; C23C 28/04; H01M 10/0562; C23C 16/455; C23C 22/05; C23C 18/12

(52) U.S. Cl. CPC C23C 22/70; C23C 16/405; C23C 28/042; H01M 10/0562; C23C 16/45555; C23C 22/05; C23C 18/1216; C23C 18/1295; H01M 2300/0077; Y02E 60/10; H01M 10/0525

(57) ABSTRACT

Forming a lithium lanthanum zirconate thin film includes disposing zirconium oxide on a substrate to yield a zirconium oxide coating, contacting the zirconium oxide coating with a solution including a lithium salt and a lanthanum salt, heating the substrate to yield a dried salt coating on the zirconium oxide coating, melting the dried salt coating to yield a molten salt mixture, reacting the molten salt mixture with the zirconium oxide coating to yield lithium lanthanum zirconate, and cooling the lithium lanthanum zirconate to yield a lithium lanthanum zirconate coating on the substrate. In some cases, the zirconium oxide coating is contacted with an aqueous molten salt mixture including a lithium salt and a lanthanum salt, the molten salt mixture is reacted with the zirconium oxide coating to yield lithium lanthanum zirconate, and the lithium lanthanum zirconate is cooled to yield a lithium lanthanum zirconate coating on the substrate.

### CROSS-REFERENCE TO RELATED APPLICATIONS

This application is a continuation of U.S. application Ser. No. 17/685,923 entitled “LITHIUM LANTHANUM ZIRCONATE THIN FILMS” and filed on Mar. 3, 2022, which claims is a divisional of U.S. application Ser. No. 16/669,767, now U.S. Pat. No. 11,268,196, entitled “LITHIUM LANTHANUM ZIRCONATE THIN FILMS” and filed on Oct. 31, 2019, which claims the benefit of U.S. Application No. 62/753,503 entitled “LITHIUM LANTHANUM ZIRCONATE THIN FILMS” and filed on Oct. 31, 2018, which are incorporated herein by reference in their entirety.

### STATEMENT OF GOVERNMENT INTEREST

This invention was made with government support under 1553519 awarded by the National Science Foundation. The government has certain rights in the invention.

### TECHNICAL FIELD

This invention relates to methods of fabricating conformal lithium lanthanum zirconate (LLZO) thin films and the resulting films.

### BACKGROUND

To realize the next generation of all-solid-state lithium batteries with three-dimensional (3D) architectures for high energy and power capability, new methods for the deposition of solid state electrolytes (SSEs) are needed. Atomic layer deposition (ALD) can be used to deposit thin films onto 3D substrates. However, the development of SSEs with high Li⁺ ionic conductivity using ALD is challenging due to the limited suitable precursors available and the complex, multi-element compositions of the materials.

### SUMMARY

As described herein, lithium lanthanum zirconate (Li₇La₃Zr₂O₁₂ or LLZO) thin films can be synthesized in a molten salt medium from atomic-layer deposition (ALD) ZrO₂ thin films serving as a conformal seed layer. This molten-salt mediated deposition of LLZO is effective for forming conformal thin films on 3D substrates with high aspect ratios (e.g., greater than 50, greater than 100, and less than 200, or less than 150). The formed LLZO is highly crystalline (cubic phase), and has an ionic conductivity ˜10⁻⁴-10⁻³ S/cm, and a controlled thickness from ˜100 nm to 10 μm. This facilitates the fabrication of 3D electrodes for Li batteries with enhanced volumetric energy density and power. The synthesis take less reaction time than ALD methods for depositing the LLZO material, and can yield materials with better crystallinity and ionic conductivity compared to ALD, CVD, and sputtering methods.

In a first general aspect, coating a substrate includes disposing zirconium oxide on a substrate to yield a zirconium oxide coating on the substrate, contacting the zirconium oxide coating with a solution including a lithium salt and a lanthanum salt with, heating the substrate to yield a dried salt coating on the zirconium oxide coating, melting the dried salt coating to yield a molten salt mixture, reacting the molten salt mixture with the zirconium oxide coating to yield lithium lanthanum zirconate, and cooling the lithium lanthanum zirconate to yield a lithium lanthanum zirconate coating on the substrate.

In a second general aspect, coating a substrate includes disposing zirconium oxide on a substrate to yield a zirconium oxide coating on the substrate, heating an aqueous mixture comprising a lithium salt and a lanthanum salt to yield a molten salt mixture, contacting the zirconium oxide coating with the molten salt mixture, reacting the molten salt mixture with the zirconium oxide coating to yield lithium lanthanum zirconate, and cooling the lithium lanthanum zirconate to yield a lithium lanthanum zirconate coating on the substrate.

Implementations of the first and second general aspects may include one or more of the following features.

Disposing zirconium oxide on the substrate may include atomic layer deposition or plasma-enhanced atomic layer deposition of zirconium oxide on the substrate. In some cases, the substrate is planar. In certain cases, the substrate includes protrusions and recessions. Disposing the zirconium oxide on the substrate may further include disposing additional zirconium oxide on the zirconium oxide coating with a chemical vapor deposition or sol-gel process. The zirconium oxide used to form the zirconium oxide coating may be in the form of zirconium oxide nanoparticles. In some cases, the zirconium oxide coating is amorphous.

Contacting the zirconium oxide coating with the solution may include spraying the solution on the zirconium oxide coating or drop casting the solution on the zirconium oxide coating. The lithium salt may include lithium nitrate, the lanthanum salt may include lanthanum nitrate, or both. The solution may be homogeneous. In certain cases, the solution includes a polar solvent (e.g., water or an organic solvent such as methanol). The solution may further include a zirconium salt (e.g., a nitrate salt). Contacting the zirconium oxide coating with the molten salt mixture may include immersing the substrate in the molten salt mixture. The aqueous solution may include a zirconium salt.

Heating the substrate may include removing liquid from the solution. Melting the dried salt coating may include heating the substrate to at least 400° C., at least 450° C., at least 800° C. or at least 900° C. Contacting the solution with the zirconium oxide coating may include wetting the zirconium oxide coating with the solution.

The lithium lanthanum zirconate coating may be polycrystalline or nanocrystalline. A thickness of the lithium lanthanum zirconate coating is typically in a range of 1 micron to 10 microns.

The details of one or more embodiments of the subject matter of this disclosure are set forth in the accompanying drawings and the description. Other features, aspects, and advantages of the subject matter will become apparent from the description, the drawings, and the claims.

### BRIEF DESCRIPTION OF THE DRAWINGS

FIG. 1A depicts a portion of a solid-state battery with a three-dimensional (3D) cathode and a planar anode. FIG. 1B depicts a portion of a solid-state battery with 3D interdigitated electrodes.

FIG. 2 depicts a process for fabricating a conformal lithium lanthanum zirconate (LLZO) thin film on a 3D substrate.

FIG. 3 depicts deposition of a thin film of ZrO₂ onto a substrate using atomic layer deposition (ALD), followed by spray deposition of a salt mixture onto the substrate coated by ALD.

FIG. 4A depicts molten salt synthesis (MSS) mediated formation of LLZO on a ZrO₂ thin film. FIG. 4B depicts a mechanism for the formation of LLZO thin films on a ZrO₂ thin film using a MSS mediated reaction.

FIGS. 5A and 5B show SEM images of ZrO₂ nanoparticles and a product obtained by MSS at 800° C., respectively. FIG. 5C shows an X-ray diffraction (XRD) spectrum of LLZO formed by MSS.

### DETAILED DESCRIPTION

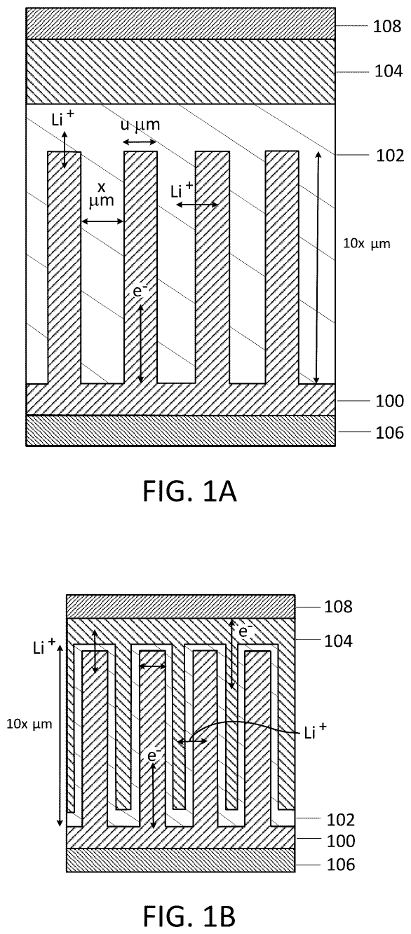

Three-dimensional (3D) battery electrodes that utilize solid-state electrolytes (SSEs) have attracted much interest because of their potential for improved energy and power densities and safety characteristics. Two example 3D battery architectures are shown in FIGS. 1A and 1B. In FIG. 1A, 3D structured cathode 100 (either a plate or pillar array) is infiltrated with SSE 102 and paired with planar anode 104. Cathode 100 and anode 104 contact current collectors 106 and 108, respectively. In FIG. 1B, a conformal SSE 102 deposited on 3D cathode 100 enables infiltration with a 3D anode 104 to form interdigitated plates (or pillars). In both cases, high aspect ratios of 100 (e.g. where x is the plate (or pillar) thickness, the plate (or pillar) height is 10x, and x=10-20 μm) are typically required for the desired energy and power enhancements over planar batteries. A desired thickness of the SSE can be in a range of about 1-10 μm.

To realize both types of structures, a method to conformally deposit SSEs into high aspect ratio structures is described. For thin films of SSE, the electrolyte resistance (R) is determined by R=l(σA)⁻¹, where l is the thickness and σ is the Li⁺ ionic conductivity. For a SSE with σ˜10⁻⁷ S/cm, a thin film is typically no more than 1 μm in thickness to have comparable electrolyte resistance to the best bulk SSEs ˜1 mm thick with σ˜10⁻⁴ S/cm. Chemical vapor deposition (CVD) methods can provide thin films with better conformality than physical deposition methods (e.g., pulsed laser deposition or sputtering) but are limited for high aspect ratio designs. Atomic layer deposition (ALD) allows deposition of pinhole-free films on substrates with high aspect ratios on account of the self-limiting nature of the surface reactions in ALD.

In some cases, ALD methods are limited to depositing thin films only on the order of a few hundred nanometers. For at least this reason, ALD thin films are typically not well suited for depositing SSEs in 3D architectures like the one illustrated in FIG. 1A, where channels (voids) separating the electrode plates/pillars that need to be filled are ˜10 μm.

The development of ALD methods for battery materials for high energy and high power applications has many technical obstacles. In general, it is challenging to develop ALD processes for Li-containing materials due to the limited options for suitable volatile Li precursors. Garnet-type Li₇La₃Zr₂O₁₂ (LLZO) has high ionic conductivity and chemical stability against both air and metallic lithium. Due at least in part to the complex composition and structure, it can be a challenge to obtain high quality LLZO using vapor deposition processes, with ALD of LLZO typically requiring multiple sub-cycles of each constituent element as its binary oxide. LLZO is conventionally prepared using a solid-state reaction from LiOH or Li₂CO₃, La₂O₃, and ZrO₂, along with oxides of dopants (e.g., Al₂O₃) as reagents at high temperatures (>1100° C.) and long sintering times (24+ hours) to obtain the desired crystal structure and ionic conductivity. The cubic phase of LLZO generally displays Li-ion conductivity on the order of 0.1-1 mS/cm, depending on the extrinsic dopant used to stabilize the metastable cubic phase at room temperature. In the absence of dopants, the tetragonal phase is obtained, which has 3-4 orders of magnitude lower ionic conductivity.

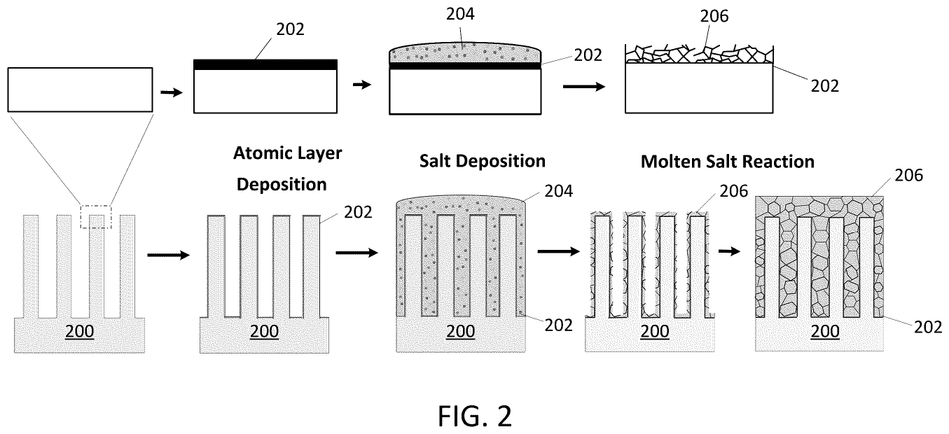

Referring to FIG. 2, the process described herein combines the conformal nature of ALD with a synthetic method that enables the formation of high quality, crystalline LLZO. As depicted in FIG. 2, substrate electrode 200 is coated with a layer of ZrO₂ 202 deposited by ALD. In some cases, plasma-enhanced ALD (PEALD), which can yield films with good conformality and high density and purity, may be used to deposit the ZrO₂ coating. The ZrO₂ coating is typically conformal, in that it conforms to the contours of the substrate to which it is applied. The ZrO 2 coating is believed to be an effective interphase or buffer layer to prevent undesired side reactions at the interface between the electrode active material and the solid-electrolyte. A suitable deposition temperature may be as low as 100° C., advantageously preventing damage or side reactions with the substrate.

In some cases, additional ZrO₂ can be deposited on top of the pinhole free ALD ZrO₂ layer. This can be accomplished by using chemical vapor deposition (CVD), sol-gel chemistry, or adding additional Zr reagent in the MSS (e.g., zirconium oxynitrate). If the ZrO₂ layer exceeds a certain thickness, some unreacted ZrO₂ may remain at the interface between the substrate and the LLZO. This remaining ZrO₂ may provide a good surface passivation layer for battery materials, serve as a buffer layer, or both.

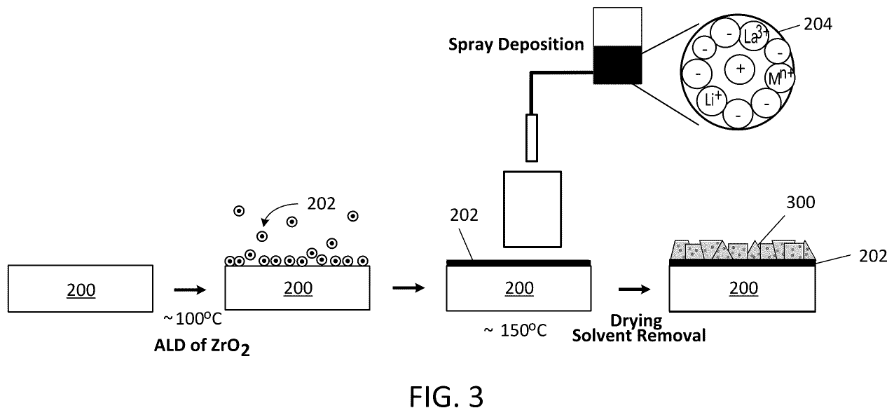

The ZrO₂ coating also serves as a seed layer for the formation of LLZO using a topochemical, molten salt synthesis (MSS) mediated conversion process, allowing the formation of a thin film of crystalline LLZO with high ionic conductivity on the substrate. Once the ZrO₂ layer is deposited, solution 204 containing LLZO precursor salts and MSS salts is applied to the surface, for example using spray deposition, as depicted in FIG. 3. In this approach, a solution including a lithium salt (e.g., lithium nitrate) and a lanthanum salt (e.g., lanthanum nitrate) is first dissolved in water and homogenously mixed. In some cases, the solution includes a zirconium salt (e.g., zirconium oxynitrate). One or more dopants (e.g., Al, Ga, Ta) may be incorporated in the molten salt as salt or oxidic precursors. The molten salt synthesis salts may include eutectic mixtures of halide, carbonate, nitrate, peroxide, or hydroxide salts, or any combination thereof, which become liquid at temperatures exceeding the eutectic temperature (T e) of the mixture. The solution 204 is then sprayed onto a substrate, and this substrate is placed in an oven or heated on a hot plate, in order to volatilize the solvent and leave the dried salts 300 deposited as a thin film on the substrate 200. Alternatively, an ultrasonic nebulizer can also be used to atomize the solution and deposit fine droplets<5 μm in size. Further film growth in the salt melt can result in thicknesses on the order of several microns. Thus, as depicted in FIG. 2, LLZO layer 206 can be formed within a 3D electrode architecture.

In some cases, due at least in part to the “shadow effect,” spray deposition may not be effective for depositing the salt reactants onto 3D substrates with extremely high aspect ratios. However, for a 3D electrode architecture as depicted in FIG. 2, it is expected that a solution containing the salt precursors can be dried within the voids by drop casting and drying. In certain cases, the entire electrode can also be immersed in the molten salt solution.

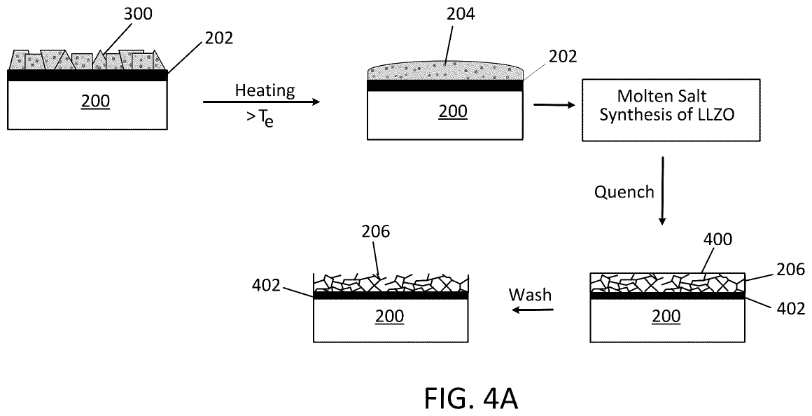

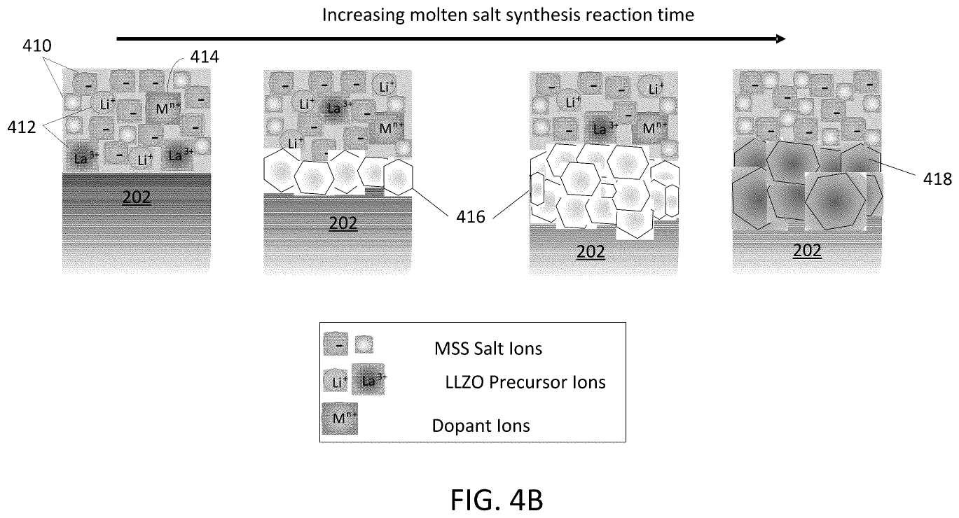

As depicted in FIG. 4A, the thin film salt mixture is dried to yield dried salts 300, and the substrate 200 is then heated above the eutectic temperature of the MSS medium in order to melt the salts, redissolve the LLZO precursor salts, and enable the ZrO₂ to react within the medium to form LLZO 206. In some cases, the salts form a liquid film on the ZrO₂ that allows the reactants to diffuse down into the film. It is expected that La₂Zr₂O₇ (LZO), in the form of a nanocrystalline film, will present as the intermediate phase and eventually transform to a polycrystalline LLZO film upon further reaction with Li and La precursor salts. This LZO to LLZO transformation is believed to be topochemical in nature. When the LLZO reaction has completed and the substrate is cooled below the eutectic temperature, the salt medium solidifies. Cooled salt medium 400 is removed by washing (e.g., with methanol) to avoid significant Li⁺/H⁺ exchange on the surface of the LLZO, which can decrease the ionic conductivity.

FIG. 4B depicts a mechanism for MSS mediated formation of LLZO. As depicted in FIG. 4B, dried salt layer 300 is disposed on ZrO₂ layer 202. Dried salt layer 300 includes MSS salt ions 410, LLZO precursor ions 412 (Li⁺, La³⁺), and dopant ions 414 (Mil. As the MSS reaction proceeds, an LZO layer 416 is formed, and is transformed into M-doped LLZO layer 418.

Upon heating, the liquid layer is expected to achieve appropriate wetting of the surface of the ZrO₂, so that it does not form discrete portions, thereby resulting in a discontinuous LLZO film, or fully spread, thereby enhancing volatilization of the salt medium or prevent sufficient volume of liquid for the reaction. The immersion of the ZrO₂-coated substrates directly into the molten salt melt (i.e., in a crucible), may provide desired results, with the salt melt containing the Li and La salt precursors and the Zr provided by the ALD layer. Assuming that LLZO will only form on the surface of the ZrO₂, this approach is expected to result in a thin film of LLZO. This immersion approach may also be more amenable for the formation of LLZO on 3D substrates, as the liquid salt mixture easily penetrates the pores. Once the seed layer of LLZO (nucleated from the ALD ZrO₂) is formed, then additional LLZO can be grown to form thicker films via MSS using Li, La, Zr, and dopant reactants.

Methods described herein have several advantages that can address the aforementioned challenges of ALD processes for SSE materials. Performing ALD of a binary oxide (ZrO₂) simplifies the deposition process and eliminates the need for using sub-cycles in order to obtain films with the desired composition. Moreover, the ALD layer of ZrO₂ does not have to be crystalline to serve as a seed layer, enabling lower temperature ALD deposition. This could mitigate the interdiffusion of cations at the interface between the ZrO₂ and electrode active material, which can be detrimental to surface properties of the electrode and can cause high interfacial impedance during electrochemical cycling. LLZO prepared by MSS is crystalline and has comparable ionic conductivity (˜10⁻⁴ S/cm) to materials prepared by solid-state reaction. The molten salt medium can also be used to increase the thickness of the initial LLZO thin film nucleated from the ALD ZrO₂ thin film.

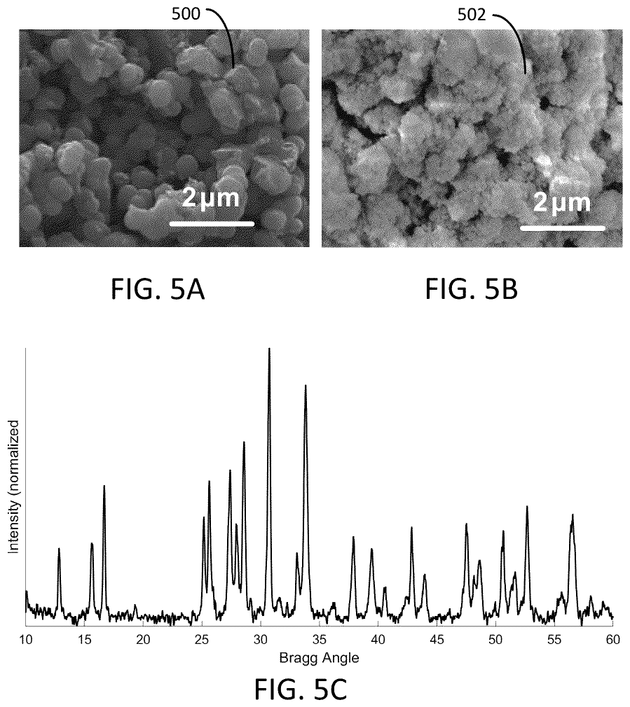

ZrO₂ nanoparticles (zirconium source for the preparation of LLZO using the MSS reaction) were prepared using a sol-gel precipitation reaction from zirconium butoxide. FIG. 5A is a scanning electron microscope (SEM) image of the resulting ZrO₂ nanoparticles 500. FIGS. 5B and 5C show a SEM image an X-ray diffraction (XRD) pattern, respectively, of the LLZO product 502 obtained after MSS reaction at 800° C. in a LiCl/KCl eutectic mixture. The XRD pattern shows that the primary phase of the product is cubic LLZO, with secondary products present due to unoptimized reaction conditions.

Thus, LLZO formation was observed at 800° C., 100 degrees lower than when using Zr(NO₃)₂ as the precursor, consistent with the decreased formation temperature on account of heterogenous nucleation of LLZO on the ZrO₂. It is believed that LLZO formation may occur at temperatures as low as 400° C., or as low as 450° C. The transformation of the ZrO₂ to LLZO is believed to be topochemical in nature, as the nanoparticle morphology was preserved in the LLZO product. This result, together with the low solubility of ZrO₂ in the LiCl/KCl eutectic, suggests that the formation of LLZO is not a dissolution-precipitation reaction, but rather a transformation of the ZrO₂ into LLZO upon reaction with the LLZO precursors in this reactive salt medium. As such, the formation of LLZO is possible from amorphous ZrO₂ nanoparticles. Similarly, it is believed that the formation of LLZO is also possible from ZrO₂ thin films.

U.S. Patent Publication No. 2019/0062176, which is incorporated herein by reference, describes the synthesis of LLZO using a molten salt reaction. U.S. patent application Ser. No. 16/399,331, which is incorporated herein by reference, describes the synthesis of LLZO thin films by mixing Li and La salts with lanthanum zirconate nanocrystals to form a slurry, followed by tape casting and sintering to form thin films.

Although this disclosure contains many specific embodiment details, these should not be construed as limitations on the scope of the subject matter or on the scope of what may be claimed, but rather as descriptions of features that may be specific to particular embodiments. Certain features that are described in this disclosure in the context of separate embodiments can also be implemented, in combination, in a single embodiment. Conversely, various features that are described in the context of a single embodiment can also be implemented in multiple embodiments, separately, or in any suitable sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

Particular embodiments of the subject matter have been described. Other embodiments, alterations, and permutations of the described embodiments are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results.

Accordingly, the previously described example embodiments do not define or constrain this disclosure. Other changes, substitutions, and alterations are also possible without departing from the spirit and scope of this disclosure.

1-26. (canceled)

27. A coated substrate formed by a coated substrate comprising:
disposing zirconium oxide on a substrate to yield a zirconium oxide coating on the substrate;
contacting the zirconium oxide coating with a solution comprising a lithium salt and a lanthanum salt;
heating the substrate to yield a dried salt coating on the zirconium oxide coating;
melting the dried salt coating to yield a molten salt mixture;
reacting the molten salt mixture with the zirconium oxide coating to yield lithium lanthanum zirconate; and
cooling the lithium lanthanum zirconate to yield the coated substrate, wherein the coated substrate comprises a lithium lanthanum zirconate coating on the substrate.

28. The coated substrate of claim 27, wherein the zirconium oxide used to form the zirconium oxide coating is in the form of zirconium oxide nanoparticles.

29. The coated substrate of claim 27, wherein the zirconium oxide coating is amorphous.

30. The coated substrate of claim 27, wherein the lithium salt comprises lithium nitrate.

31. The coated substrate of claim 27, wherein the lanthanum salt comprises lanthanum nitrate.

32. The coated substrate of claim 27, wherein the solution further comprises a zirconium salt.

33. The coated substrate of claim 32, wherein the zirconium salt comprises a nitrate salt.

34. The coated substrate of claim 27, wherein the substrate is planar.

35. The coated substrate of claim 27, wherein the substrate comprises protrusions and recessions.

36. The coated substrate of claim 27, wherein the lithium lanthanum zirconate coating is polycrystalline or nanocrystalline.

37. The coated substrate of claim 27, wherein a thickness of the lithium lanthanum zirconate coating is in a range of 1 micron to 10 microns.

38. A coated substrate formed by a coated substrate comprising:
disposing zirconium oxide on a substrate to yield a zirconium oxide coating on the substrate;
heating an aqueous mixture comprising a lithium salt and a lanthanum salt to yield a molten salt mixture;
contacting the zirconium oxide coating with the molten salt mixture;
reacting the molten salt mixture with the zirconium oxide coating to yield lithium lanthanum zirconate; and
cooling the lithium lanthanum zirconate to yield the coated substrate, wherein the coated substrate comprises a lithium lanthanum zirconate coating on the substrate.

39. The coated substrate of claim 38, wherein the molten salt mixture comprises one or more metal dopants.

40. The coated substrate of claim 39, wherein the metal dopants comprise salt precursors, oxidic precursors, or any combination thereof.

41. The coated substrate of claim 39, wherein the metal dopants comprise aluminum, gallium, tantalum, or any combination thereof.

42. The coated substrate of claim 38, wherein the molten salt mixture comprises halide, carbonate, nitrate, peroxide, or hydroxide salts, or any combination thereof.

43. The coated substrate of claim 38, wherein the substrate is planar.

44. The coated substrate of claim 38, wherein the substrate comprises protrusions and recessions.

45. The coated substrate of claim 38, wherein the lithium lanthanum zirconate coating is polycrystalline or nanocrystalline.

46. The coated substrate of claim 38, wherein a thickness of the lithium lanthanum zirconate coating is in a range of 1 micron to 10 microns.
